(19) United States
(12) Patent Application Publication
(10) Pub. No.: US 2007/0018752 A1
(43) Pub. Date: Jan. 25, 2007

(54) OPTIMIZATION OF THROUGH PLANE TRANSITIONS

(75) Inventor: William A. Miller, Camas, WA (US)

Correspondence Address: MARGER JOHNSON & MCCOLLOM, P.C., 210 SW MORRISON STREET, SUITE 400, PORTLAND, OR, 97204, US

(73) Assignee: EFFICERE, LLC, Vancouver, WA (US)

(21) Appl. No.: 11/421,393

(22) Filed: May 31, 2006

Related U.S. Application Data
(60) Provisional application No. 60/701,138, filed on Jul. 20, 2005.

(51) Int. Cl. H03H 7/38

(52) U.S. Cl. 333/33

(57) ABSTRACT

A substrate includes a first metal layer containing a first trace, a second metal layer containing a second trace and a dielectric layer arranged between the first and second metal layers. The substrate also includes an electrically conductive signal via electrically coupled to the first and second traces traversing the dielectric layer to form a signal path, wherein physical characteristics of the via are controlled such that signal path characteristics of the via match signal path characteristics of the first and second traces.

This application is a continuation of, and claims priority to, U.S. Provisional Application No. 60/701,138, filed Jul. 20, 2005, and is incorporated herein by reference.

### BACKGROUND

Printed circuit boards (PCBs) or other circuit substrates are often constructed of multiple layers, with connections from the surface of the substrate being connected to inner layer traces of the substrate. For signal integrity, the impedance of the signal path from one point to another should be a constant as possible. With transitions between layers in a substrate, there is a high probability of impedance mismatch between a signal path through a first layer, the transition to a second layer and the signal path through the second layer. This causes overall impedance mismatch in the signal path from end to end, resulting in degraded signal integrity at the receiving end.

### BRIEF DESCRIPTION OF THE DRAWINGS

Embodiments of the invention may be best understood by reading the disclosure with reference to the drawings, wherein:

FIG. 1 shows a three-dimensional view of a circuit substrate.

FIG. 2 shows an alternative three-dimensional view of a circuit substrate.

FIG. 3 shows an embodiment of an annular ring at a layer transition.

FIG. 4 shows an embodiment of annular rings at an inner layer.

FIG. 5 shows a flowchart of an embodiment of a method of designing a substrate.

FIG. 6 shows a cross-sectional side view of a circuit substrate with clad vias.

FIG. 7 shows a top view of a circuit substrate having a signal via and reference vias.

FIG. 8 shows a top view of a circuit substrate showing alternative placements of reference vias around a signal via.

FIG. 9 shows a cross-sectional side view of a circuit substrate having an interlayer transition.

### DETAILED DESCRIPTION OF THE EMBODIMENTS

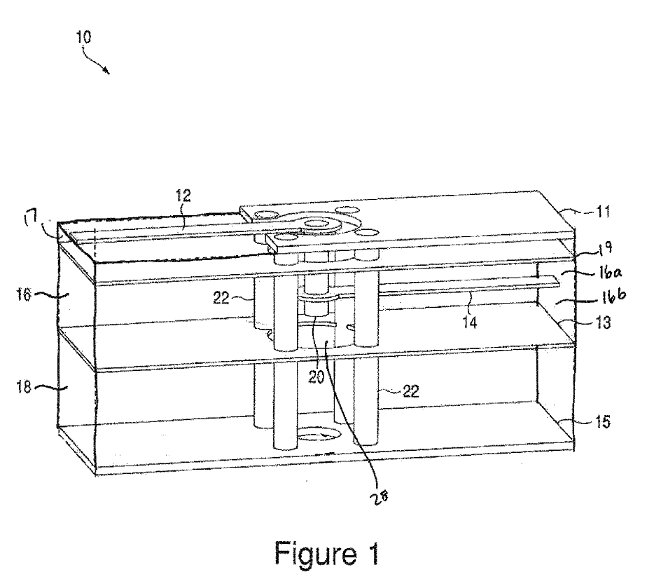

FIG. 1 shows three-dimensional view of a circuit substrate. The board as shown has five layers of conductive material 11, 14, 13, 15 and 19 such as copper clad and four layers of dielectric 16, which is one layer on the side without the conductive layer 14, and two layers 16a and 16b on the side with the conductive layer 14, 17 and 18 between them. The conductive layers may take the form of traces. However, it must be noted that this is merely an example and the embodiments disclosed here may apply to any number of layers. The dielectric may be any typical dielectric material used in substrates of this nature. Generally, lower dielectric constant (k) materials are becoming prevalent as circuit substrate dielectrics.

The circuit substrate 10 has a top surface 11, which may include traces. An example of a trace is shown at 12. The circuit substrate has layers 16, 17 and 18, shown here as a dielectric. In this example, layer 16 is a single layer on the left side of the diagram and divided into two sublayers 16a and 16b on the right side. On the left side, the layer 16 may actually be formed of two different dielectric materials, one on the top of the strip line 14 and the other below, but on the left side, they form one layer of dielectric between conductive layers. The strip line 14 is connected to the trace 12 by a via 20 that has been back drilled or stub drilled to minimize the stub effect of the via, discussed in more detail later.

It must be noted that the transition shown here is from a microstrip through a plated via to an internal stripline. Application of the invention is not restricted to this occurrence. The transition could be from a microstrip or other surface trace to another microstrip or surface trace coplanar waveguides. Alternatively, the transition could be from a stripline in one layer to a stripline in another layer completely internal to the circuit substrate. For ease of discussion, here, however, the transition will be from a surface microstrip to an internal stripline, with the understanding that the via 20 may traverse a dielectric layer to form a connection between two metal layers.

The metal stub of the signal via 20 may be formed from a metal-plated via through the substrate 10. Currently, metal stubs such as 20 are typically formed as a metal-plated via through the substrate which may then be optionally back-drilled to minimize the stub beyond the stripline trace, from the bottom of the substrate in the orientation shown in FIG. 1, leaving a significantly reduced metal stub 20. The depth of the metal stub beyond the strip line is currently not optimized with regard to particular signal characteristics in light of manufacturing process limitations and may form reflections in the path that affects the signal integrity due to the reflected energy trapped in the metal stub.

The signal path via 20 is electrically connected to the microstrip 12 and the strip line 14, allowing signals traveling through the microstrip 12 to transition into the layers of the circuit board and into strip line 14. The signal via 20 may transition through the layers having apertures such as 28. These transitions, as well as the differences between the microstrip 12, the signal path via 20 and the strip line 14, may result in mismatches or irregularities in the signal path characteristics.

Signal path characteristics as used here means measurable qualities of an electrical signal in the path. These include but are not limited to impedance, including components of impedance of inductance, capacitance, resistance, and conductance; return loss; insertion loss; cross talk; and attenuation.

In situations where impedance mismatch arises, there is a disturbance in the electromagnetic (EM) field around a signal path. This can affect the signal strength, causing loss in the signal. In more extreme cases, for example, a signal that has a voltage level associated with a logic level ‘1’ may experience enough loss that when it reaches the other end of the signal path is has a voltage level associated with a logic level ‘0.’

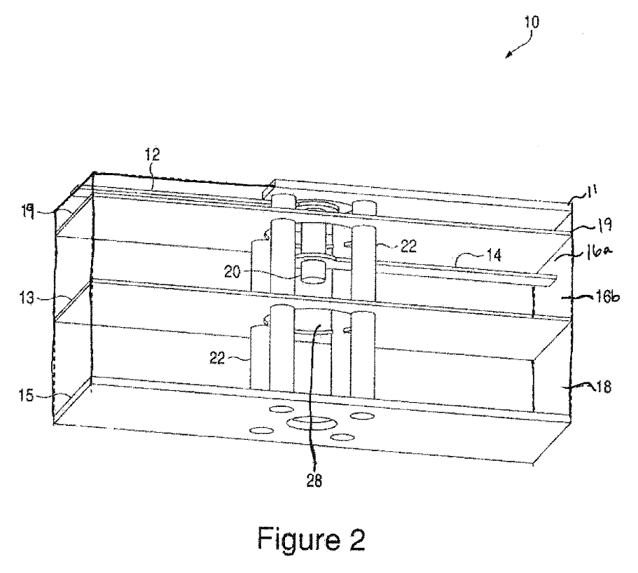

Return loss is generally affected by the location of the ground plane relative to the signal path due to reflections associated with the mismatch of impedance between signal vias and references vias. As can be seen in FIGS. 1 and 2, reference vias such as 22 surround the signal path via 20 from FIG. 1. The placement of these reference vias relative to the signal path via 20 may have a drastic effect on the signal integrity in the signal path.

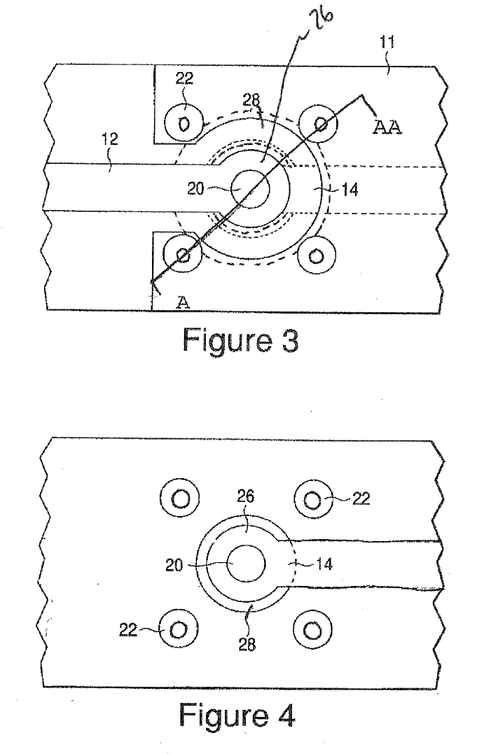

In addition to the placement of the reference vias, annular rings used in the manufacturing process may be controlled for the signal characteristics as well. An example of such a ring at a surface of a substrate is shown at 26 in FIG. 3. FIG. 4 shows an annular ring 26 on an interlayer of the substrate. The term ‘annular ring’ is a term used in manufacturing of the substrate. The presence of an annular ring allows more consistent connection to the drilled and plated of the hole forming the via. The annular ring and the other portions of the structure that provide electrical connection may also be referred to as the ‘pad.’

In future embodiments, it may be possible and desirable to eliminate the annular ring, in which case the connection would be directly to the metal lining the via, without the annular ring. For example, if via size and drill size were small enough, the via may be drilled such that the circumference of the via is contained within the trace, with no need for an annular ring.

It is possible to optimize the formation of the annular ring 26, the placement of the reference vias 22 and the aperture 28 to eliminate or mitigate mismatches and irregularities in the signal path characteristics. As mentioned above, currently substrate manufactures are concentrating on the annular ring and optimizing the formation of that to minimize impedance in the outer layer. The formation of the annular ring in this example, as well as any other apertures in any other layers, may be tuned to a particular electrical characteristic, such as impedance, of the signal path in that layer.

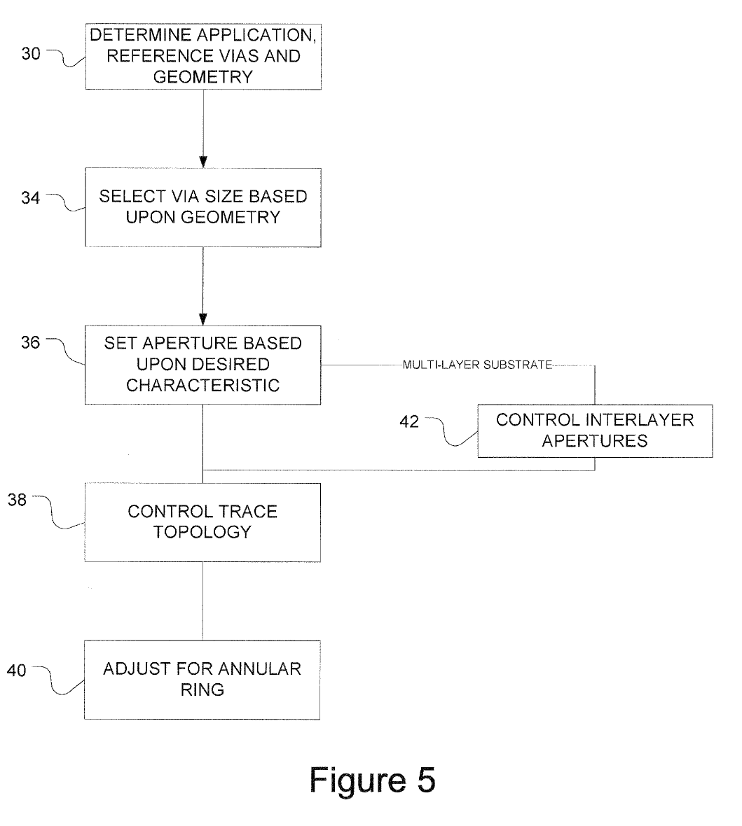

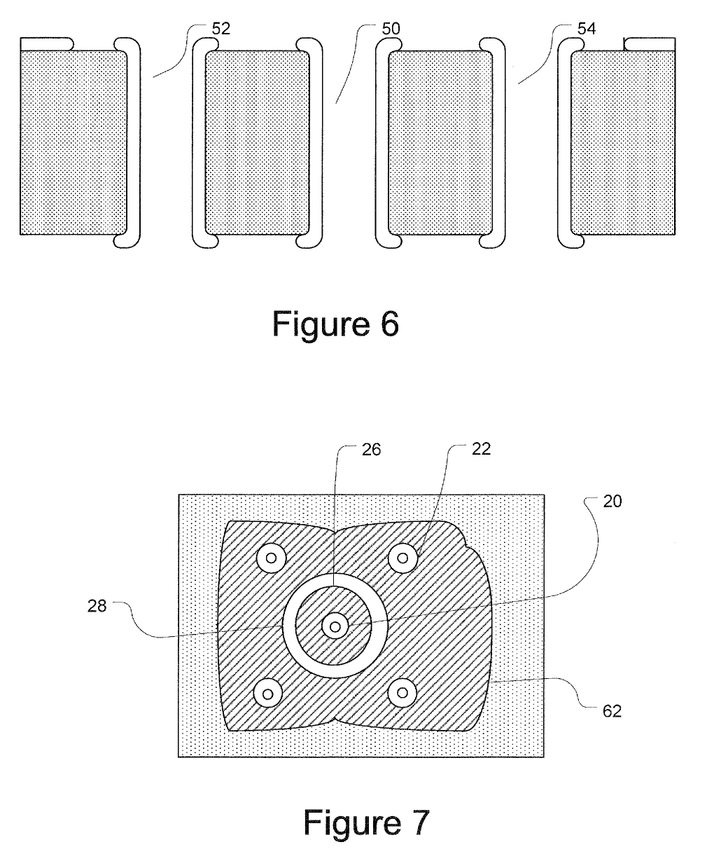

A method of designing a signal path to manage a selected signal characteristic is shown in FIG. 5. For ease of discussion, a cross-section through a substrate, such as along line A-AA in FIG. 3 is shown in FIG. 6. For ease of discussion and better understanding, the process will focus first on a simple substrate having a via from a trace on one side of the substrate to a trace on the other side of the substrate.

In FIG. 6, the signal via 50 has reference vias 52 and 54 on either side of it. The size of the signal via, the number of reference vias, the distance between the signal via and the reference vias, the application of the via, whether for single signals or differential signals, are determined at 30 in FIG. 5. The determination may take into account the size of the substrate, the nature of the connectors, the design rules used in designing and laying out the circuitry, etc.

The number of reference vias may be guided by the size of the area provided for the vias, the application and geometry of the signal vias, the circuit requirements, etc. The placement of the reference vias relative to the signal via and each other may be used to control the desired signal characteristics as will be discussed further.

In 34, the via size is selected based upon the determinations made in 30. If a drill is used to form the via, the drill size is selected based upon the geometry of the via. It must be noted that in current implementations, other means may be used to make the hole such as by laser drilling and are considered to be included in this discussion. Therefore, the drill size selection is considered to be an optional process.

In 36, an aperture, sometimes referred to as an anti-pad, is set. Referring back to FIGS. 3 and 4, the aperture 28 is the area around the via that is ‘outside’ the annular ring 26. In one embodiment, using a three-dimensional, electromagnetic (EM) solver tool, a ‘port’ may be defined to be in the area of the aperture with a particular signal characteristic. This process is iterated until the structure being tested meets the desired characteristic.

In 42, the aperture on each layer may be dealt with differently depending upon the signal via, reference vias, dielectric thickness and characteristic above and below the trace, the stub, the annular ring, etc.

For the embodiment under discussion here, once the aperture is set at 36, the process moves to controlling the trace topology. In one embodiment, the trace is treated as a co-planar waveguide for modeling purposes. A co-planar waveguide is a trace topology that has two reference traces on either side of the signal trace, separated by a gap, typically air on the same plane.

Using a co-planar waveguide model, it is possible to determine the layout of the surface topology. Referring to FIG. 7, it can be seen that the surface can be viewed as a metal pad 62 encompassing the area around the via 20, the annular ring 26, if there is one, and the aperture or air gap 28. This surface is modeled as a co-planar waveguide and adjustments are made to the topology to ensure that the signal characteristics are maintained.

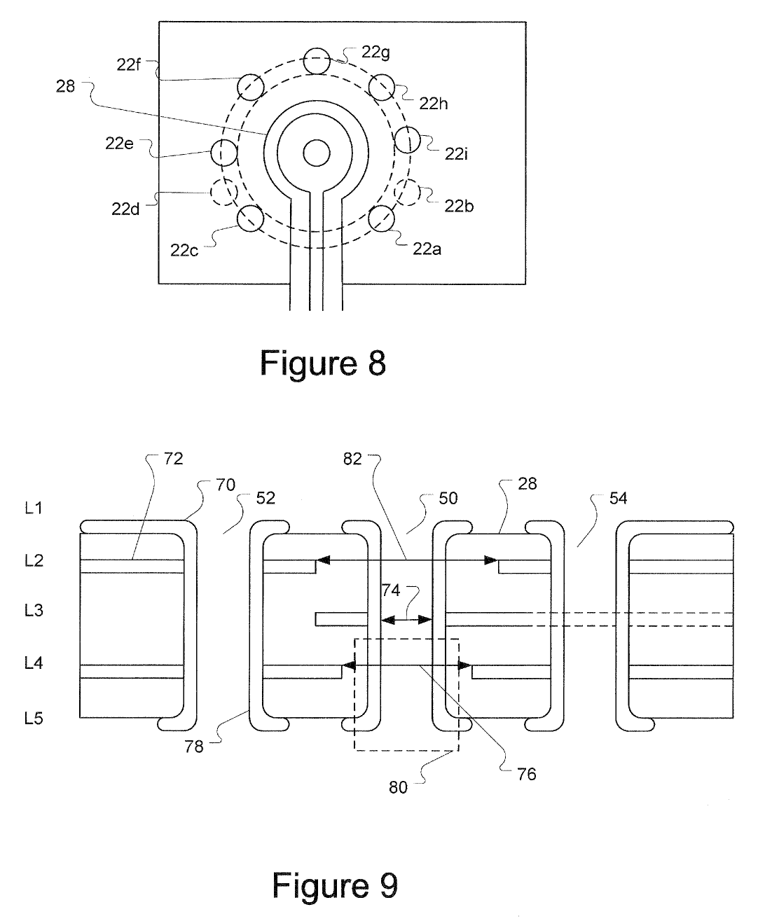

As can be seen in FIG. 8, the position and number of the reference vias such as 22a-i may change depending upon the application. Referring to FIG. 5, the number of reference vias available for adjustment is generally determined prior to this process within 30. However, there is no limitations to a particular number of vias being used, so alternative arrangements are presented. During the setting of the aperture 28, typically also done previous to this process, the aperture may have been adjusted to many different possible positions, including those shown by the dotted circles. The aperture may intersect with the reference vias, be smaller than a circle defined by the reference vias, etc.

During the process of adjusting the trace topology at 38 of FIG. 5, the position of the reference vias may be shifted slightly. In the example of FIG. 8, the reference via 22a may be shifted slightly to the position of 22b to adjust for the presence of the co-planar waveguide. Similarly, the position of the via 22c may be adjusted such as shown at 22d. The arrangement of the other reference vias 22e-i may or may not be symmetrical, depending upon the effects of their positions on the desired signal characteristic.

Once the trace topology is set based upon the co-planar waveguide, there may be further adjustments due to the presence of the annular ring, if one is used, at 40. Typically, in current manufacturing processes, the presence of an annular ring ensures that the plating of the via is complete with no disconnects. However, in future implementations, it may be possible to drill into the via with a drill small enough that the trace itself will form the connection to the via, without use of an annular ring. Therefore, the process of adjusting for the annular ring may be optional.

Having discussed application of the embodiments of the invention for a substrate having one layer of dielectric between two metal layers, it is possible to discuss a multi-layer substrate in which there are interlayers. A cross-section of such a substrate is shown in FIG. 9.

In FIG. 9, the multi-layer substrate has five layers, which is just an example. It should be noted that the ‘layers’ referred to here are metal or conductive layers. The interposing layers of substrate dielectric are not counted as part of the layers. Layer 1 (L1) is the surface trace. The vias have been plated in this cross-section, resulting in metal cladding such as 70 and 78 on the inner walls of the vias.

Layer 2 (L2) is a reference layer, connecting to the reference via 52, but not to the signal via 50. Layer 3 (L3) is the signal layer connecting to the signal via 50. For purposes of discussion here, the reference layer 2 will be referred to as being above the signal layer. Similarly, layer 4 (L4), which is another reference layer, will be referred to as being below the signal layer. In this particular embodiment, layer 5 (L5) is the layer on the opposite surface of the substrate from the incoming signal trace.

In the interlayers, layers 2-4, the apertures of the reference layer relative to the signal via are to be set and controlled similar to the surface aperture referred to previously. The apertures may differ in each layer, however, because the effective dielectric constant is different due to the air dielectric at the surface. The aperture 82, for example, of the reference layer 2, is controlled and adjusted to maintain the desired signal characteristic. The apertures 74 and 76 may be of different sizes, due to the dielectric constant of the material used, or the thickness of the dielectric, as examples.

In the embodiment of FIG. 9, where there is a second reference layer, the aperture in the second reference layer, the one below the signal layer, is also manipulated to maintain the desired signal characteristic. The apertures involved may depend upon the relationship between the signal via, reference vias, the signal trace and the annular ring. For example, the signal via may provide connection between a surface microstrip and an interlayer stripline, between two surface microstrips as in the previous example, but through either a ‘simple’ substrate or a multi-layer substrate, or between two interlayers of the substrate. Controlling any apertures through which the signal path passes allows finer control of the properties of the signal path to maintain the desired signal path characteristic. Further, controlling the depth of the back drilling process, the resulting position of which is shown at 80, contributes to this finer control.

In this manner, the signal transition portions of the substrate are tuned and controlled so as to make the transitions have a particular target characteristic. For example, if the target characteristic is an impedance for the entire signal path of 50 ohms, the signal transitions from stripline to the various levels of the signal via to the other stripline are tuned and controlled such that the entire signal path has an impedance of 50 ohms. This may sometimes be referred to as an electrically ‘invisible via’ as any testing done shows no impedance variations at the via.

Thus, although there has been described to this point a particular embodiment for a method and apparatus for manufacture of a circuit substrate, it is not intended that such specific references be considered as limitations upon the scope of this invention except in-so-far as set forth in the following claims.

What is claimed is:

1. A substrate, comprising:
a first metal layer containing a first trace;
a second metal layer containing a second trace;
a dielectric layer arranged between the first and second metal layers; and
an electrically conductive signal via electrically coupled to the first and second traces traversing the dielectric layer to form a signal path, wherein physical characteristics of the via are controlled such that signal path characteristics of the via match signal path characteristics of the first and second traces.

2. The substrate of claim 1, wherein the first metal layer further comprises a top layer of the substrate.

3. The substrate of claim 1, wherein the second metal layer further comprises a bottom layer of the substrate.

4. The substrate of claim 1, wherein the second metal layer further comprises an internal layer of the substrate.

5. The substrate of claim 1, wherein the first metal layer further comprises an internal layer of the substrate.

6. The substrate of claim 1, the substrate further including reference vias the physical characteristics of which are controlled such that signal path characteristics of the signal via match signal path characteristics of the first and second traces.

7. The substrate of claim 1, the first trace being electrically connected to the via by an annular ring.

8. The substrate of claim 1, the first trace being electrically connected to metal lining the via.

9. The substrate of claim 1, the substrate further comprising an aperture in each metal layer and dielectric layer.

10. The substrate of claim 9, the aperture for each layer being different from apertures for the other layers.

11. The substrate of claim 1, the second metal layer further comprising a microstrip within a substrate, wherein the relationship between the via and a reference layer under the microstrip is controlled to match the signal path characteristic.

12. A method of manufacturing a substrate, comprising:
providing a dielectric layer between two metal layers;
forming a signal path through the dielectric layer with an electrically conductive via, wherein the via is formed such that the signal path has a target signal characteristic.

13. The method of claim 12, wherein forming a signal path further comprises forming an electrically conductive via through one layer and partially through another layer.

14. The method of claim 12 wherein providing a dielectric between two metal layers further comprises providing a first metal layer having a top surface, conductive traces being formed on the top surface.

15. The method of claim 12, the method further comprising electrically coupling the conductive traces to an annular ring at an entrance to the via.

16. The method of claim 15, the method further comprising electrically coupling the annular ring to a trace within a metal layer other than the layer upon which is formed the conductive traces.

17. The method of claim 12, the method further comprising forming reference vias located in positions relative to the signal via so as to control an impedance of the signal via.

18. A method of designing a signal path through a substrate, comprising:
determining an application of the signal path;
defining a geometry for a signal via in the substrate;
determining a number of reference vias available to control a signal characteristic of the signal via;
setting an aperture at a first end of the signal via, wherein the size of the aperture depends upon the signal characteristic; and
controlling a topology of at least one trace electrically coupled to the signal via.

19. The method of claim 18, wherein determining the application further comprises determining that the application is one of either a single signal, or a differential signal.

20. The method of claim 18, wherein defining a geometry further comprises defining a circumference of the signal via.

21. The method of claim 18, wherein controlling a topology of at least one trace further comprises controlling a topology of a surface trace to maintain the signal characteristic.

22. The method of claim 18, wherein the substrate further comprises a multi-layer substrate having more than two metal layers and more than one dielectric layer.

23. The method of claim 22, the method further comprising controlling apertures for at least one conductive interlayer in the substrate so as to control the signal characteristic.

24. The method of claim 23, wherein controlling apertures for at least one conductive interlayer further comprises controlling an aperture for a reference interlayer above a signal interlayer in the substrate.

25. The method of claim 24, wherein controlling apertures for at least one interlayer further comprise controlling an aperture for a reference layer below a signal interlayer in the substrate.

26. The method of claim 18, wherein controlling a topology of at least one trace further comprising controlling a topology of a surface microstrip.

27. The method of claim 22, wherein controlling a topology of at least one trace further comprises controlling a topology of a surface microstrip.

28. The method of claim 22, wherein controlling a topology of at least one trace further comprises controlling a topology of an interlayer.

29. The method of claim 18, the method further comprising adjusting for an annular ring at a connection point to the signal via.
